(19) United States
(12) Patent Application Publication
(10) Pub. No.: US 2012/0258242 A1
(43) Pub. Date: Oct. 11, 2012

(54) IN-LINE FILM-FORMING APPARATUS, METHOD OF MANUFACTURING MAGNETIC RECORDING MEDIUM, AND GATE VALVE

(75) Inventors: Yukitaka Tsunoda, Ichihara-shi (JP); Satoru Ueno, Chiba-shi (JP)

(73) Assignee: SHOWA DENKO K.K., Minato-ku, Tokyo (JP)

(21) Appl. No.: 13/515,389

(22) PCT Filed: Dec. 1, 2010
(86) PCT No.: PCT/JP2010/071469

§ 371 Date: Jun. 12, 2012

(30) Foreign Application Priority Data
Dec. 18, 2009 (JP) 2009-287679

(51) Int. Cl. G11B 5/84; F16K 3/30; C23C 16/458; F16K 31/122

(52) U.S. Cl. 427/131; 251/62; 251/326; 118/719

(57) ABSTRACT

Provided is an in-line film-forming apparatus capable of opening and closing a gate valve at a high speed while preventing the occurrence of vibration due to the opening and closing of the gate valve. In the in-line film-forming apparatus, immediately before a piston (114) in a cylinder (115) reaches an end in one direction, a second on-off valve (117a) is completely closed and air is exhausted only by a second flow rate-adjusting valve (117b). Immediately before the piston (114) in the cylinder (115) reaches an end in the other direction, a first on-off valve (116a) is completely closed and air is exhausted only by a first flow rate-adjusting valve (116b). In this way, it is possible to reduce impact due to the contact between the end of the cylinder (115) and the piston (114) and prevent the occurrence of vibration.

### TECHNICAL FIELD

The present invention relates to an in-line film-forming apparatus that performs a film-forming process while sequentially transporting a substrate, which is a deposition target, between a plurality of chambers, a method of manufacturing a magnetic recording medium using the in-line film-forming apparatus, and a gate valve that opens and closes a passage between a plurality of chambers of the in-line film-forming apparatus.

Priority is claimed on Japanese Patent Application No. 2009-287679, filed Dec. 18, 2009, the content of which is incorporated herein by reference.

### BACKGROUND ART

In recent years, in the field of magnetic recording media used in, for example, hard disk devices, recording density has significantly increased. In particular, recently, recording density has increased at the tremendous rate of approximately 1.5 times per year.

The magnetic recording medium has, for example, a structure in which a seed film, a base film, a magnetic recording film, a protective film, and a lubricant film are sequentially formed on one or both surfaces of a non-magnetic substrate. In general, the magnetic recording medium is manufactured by an in-line film-forming apparatus that performs a film-forming process while sequentially transporting the substrate held by a carrier between a plurality of chambers (for example, see PTL1).

Specifically, the in-line film-forming apparatus has a structure in which a plurality of chambers in which the film-forming process is performed is connected to each other through gate valves. In each chamber, a plurality of bearings which are supported so as to be rotatable on the horizontal axis are arranged in the direction in which the carrier is transported and the carrier can be moved on the plurality of bearings.

The carrier includes a plurality of holders and each holder includes a hole portion in which a substrate is arranged and a plurality of holding claws which are attached around the hole portion so as to be elastically deformable. The holder can removably hold the substrate inserted to the inside of the holding claws while the plurality of holding claws comes into contact with the outer circumference of the substrate.

In the in-line film-forming apparatus, the gate valve provided between the chambers opens and closes the passage through which the carrier passes. Specifically, the gate valve includes a pair of partition walls in which opening portions forming the passage are provided and a valve body which is moved and operated between the pair of partition walls. In the gate valve, after a driving mechanism, such as an air cylinder, moves the valve body in the direction in which the passage is divided, the valve body is inclined in a direction in which it comes into contact with one of the partition walls to block the opening portion during a film-forming process. On the other hand, an operation reverse to the above-mentioned operation can open the opening portion while the carrier is transported. Two gate valves may be provided between each pair of the chambers to open and close an opening portion provided in the other partition wall.

In the in-line film-forming apparatus, after each chamber is isolated by the gate valve, the internal pressure of the chamber may be reduced. In this way, it is possible to perform the film-forming process in the chambers under independent pressure conditions.

The magnetic recording medium can be continuously manufactured by the in-line film-forming apparatus. When the substrate to be processed is treated, the substrate is not contaminated, and it is possible to reduce the number of handling processes. Therefore, it is possible to improve the efficiency of the manufacturing process and manufacturing yield. As a result, it is possible to improve the productivity of the magnetic recording medium.

### CITATION LIST

### Patent Literature

[PTL1] JP-A-2002-288888

### SUMMARY OF INVENTION

### Technical Problem

However, in the in-line film-forming apparatus, in order to improve the productivity of the magnetic recording medium, it is necessary to speed up the operation of opening and closing the gate valve. However, in the in-line film-forming apparatus according to the related art, in some cases large vibration occurs in the gate valve due to the increased opening and closing speed.

Specifically, in the gate valve according to the related art, an air cylinder is used as the driving mechanism for the valve body. In this case, when the driving air pressure of the air cylinder increases, the opening/closing speed of the gate valve can be increased, but large vibration occurs in the gate valve.

In the in-line film-forming apparatus, the lifespan of the gate valve is reduced due to the vibration caused by the operation of opening and closing the gate valve at high speed. In addition, the inside of the chamber is contaminated due to abrasion caused by the operation of opening and closing the gate valve at high speed. Furthermore, when dust in the chamber is attached to the substrate due to the variation caused by the operation of opening and closing the gate valve at a high speed, the substrate comes away from the holder due to the vibration, or scratches occur in the substrate due to abrasion of the holding claws, and the quality of the manufactured magnetic recording medium is reduced.

The invention has been made in view of the above-mentioned problems, and an object of the invention is to provide an in-line film-forming apparatus capable of performing an operation of opening and closing a gate valve at a high speed while preventing the occurrence of vibration due to the operation of opening and closing the gate valve, a method of manufacturing a magnetic recording medium using the in-line film-forming apparatus, and a gate valve suitable for use in the in-line film-forming apparatus.

### Solution to Problem

The invention provides the following means.

According to a first aspect of the invention, an in-line film-forming apparatus includes: a plurality of chambers in which a film-forming process is performed; a carrier that holds a substrate, which is a deposition target, in the plurality of chambers; a transport mechanism that sequentially transports the carrier between the plurality of chambers; and a gate valve that is provided between the plurality of chambers and opens and closes a passage through which the carrier passes. The gate valve includes a pair of partition walls in which opening portions forming the passage are provided, a valve body that is moved and operated between the pair of partition walls, and a driving mechanism that drives the valve body between a position where the opening portion is blocked and a position where the opening portion is opened. The driving mechanism is an air cylinder mechanism and includes a piston that is connected to the valve body, a cylinder in which the piston is arranged, a first valve mechanism that is connected to a first space in the cylinder, and a second valve mechanism that is connected to a second space in the cylinder. In the air cylinder mechanism, air is exhausted from the second space through the second valve mechanism while being supplied to the first space through the first valve mechanism, thereby pressing and moving the piston in the cylinder in one direction in which the valve body blocks the opening portion. In the air cylinder mechanism, air is exhausted from the first space through the first valve mechanism while being supplied to the second space through the second valve mechanism, thereby pressing and moving the piston in the cylinder in the other direction in which the valve body opens the opening portion. The air cylinder mechanism reduces the flow rate of air exhausted from the second space by the second valve mechanism immediately before the piston in the cylinder reaches an end in the one direction. The air cylinder mechanism reduces the flow rate of air exhausted from the first space by the first valve mechanism immediately before the piston in the cylinder reaches an end in the other direction.

According to a second aspect of the invention, in the in-line film-forming apparatus according to the first aspect, the first valve mechanism may include a first on-off valve and a first flow rate-adjusting valve that are connected in parallel to the first space in the cylinder. The second valve mechanism may include a second on-off valve and a second flow rate-adjusting valve that are connected in parallel to the second space in the cylinder. The air cylinder mechanism may exhaust air from the second space through the second on-off valve and the second flow rate-adjusting valve while supplying air to the first space through the first on-off valve and the first flow rate-adjusting valve, thereby pressing and moving the piston in the cylinder in the one direction in which the valve body blocks the opening portion such that the second on-off valve is completely closed and air is exhausted only by the second flow rate-adjusting valve immediately before the piston reaches the end in the one direction. The air cylinder mechanism may exhaust air from the first space through the first on-off valve and the first flow rate-adjusting valve while supplying air to the second space through the second on-off valve and the second flow rate-adjusting valve, thereby pressing and moving the piston in the cylinder in the other direction in which the valve body opens the opening portion such that the first on-off valve is completely closed and air is exhausted only by the first flow rate-adjusting valve immediately before the piston reaches the end in the other direction.

According to a third aspect of the invention, in the in-line film-forming apparatus according to the second aspect, the first and second on-off valves may be electromagnetic valves, and the first and second flow rate-adjusting valves may be needle valves.

According to a fourth aspect of the invention, the in-line film-forming apparatus according to the second or third aspect may further include a guide mechanism that includes a movable body which is moved integrally with the valve body, a guide hole to which the movable body is fitted, and a resin stopper. The movable body may be moved in the guide hole to guide the valve body such that the valve body can be moved in a direction in which the passage is divided. The resin stopper may come into contact with the movable body when the movable body is disposed at least at one end of the guide hole.

According to a fifth aspect of the invention, a method of manufacturing a magnetic recording medium includes a step of forming at least a magnetic layer on a surface of a substrate using the in-line film-forming apparatus according to any one of the first to fourth aspects.

According to a sixth aspect of the invention, a gate valve that opens and closes a passage between a plurality of chambers includes: a pair of partition walls in which opening portions forming the passage are provided; a valve body that is moved and operated between the pair of partition walls; and a driving mechanism that drives the valve body between a position where the opening portion is blocked and a position where the opening portion is opened. The driving mechanism is an air cylinder mechanism and includes a piston that is connected to the valve body, a cylinder in which the piston is arranged, a first valve mechanism that is connected to a first space in the cylinder, and a second valve mechanism that is connected to a second space in the cylinder. In the air cylinder mechanism, air is exhausted from the second space through the second valve mechanism while being supplied to the first space through the first valve mechanism, thereby pressing and moving the piston in the cylinder in one direction in which the valve body blocks the opening portion. In the air cylinder mechanism, air is exhausted from the first space through the first valve mechanism while being supplied to the second space through the second valve mechanism, thereby pressing and moving the piston in the cylinder in the other direction in which the valve body opens the opening portion. The air cylinder mechanism reduces the flow rate of air exhausted from the second space by the second valve mechanism immediately before the piston in the cylinder reaches an end in the one direction. The air cylinder mechanism reduces the flow rate of air exhausted from the first space by the first valve mechanism immediately before the piston in the cylinder reaches an end in the other direction.

According to a seventh aspect of the invention, in the gate valve according to the sixth aspect, the first valve mechanism may include a first on-off valve and a first flow rate-adjusting valve that are connected in parallel to the first space in the cylinder. The second valve mechanism may include a second on-off valve and a second flow rate-adjusting valve that are connected in parallel to the second space in the cylinder. The air cylinder mechanism may exhaust air from the second space through the second on-off valve and the second flow rate-adjusting valve while supplying air to the first space through the first on-off valve and the first flow rate-adjusting valve, thereby pressing and moving the piston in the cylinder in the one direction in which the valve body blocks the opening portion such that the second on-off valve is completely closed and air is exhausted only by the second flow rate-adjusting valve immediately before the piston reaches the end in the one direction. The air cylinder mechanism may exhaust air from the first space through the first on-off valve and the first flow rate-adjusting valve while supplying air to the second space through the second on-off valve and the second flow rate-adjusting valve, thereby pressing and moving the piston in the cylinder in the other direction in which the valve body opens the opening portion such that the first on-off valve is completely closed and air is exhausted only by the first flow rate-adjusting valve immediately before the piston reaches the end in the other direction.

According to an eighth aspect of the invention, in the gate valve according to the seventh aspect, the first and second on-off valves may be electromagnetic valves, and the first and second flow rate-adjusting valves may be needle valves.

According to a ninth aspect of the invention, the gate valve according to the seventh or eighth aspect may further include a guide mechanism that includes a movable body which is moved integrally with the valve body, a guide hole to which the movable body is fitted, and a resin stopper. The movable body may be moved in the guide hole to guide the valve body such that the valve body can be moved in a direction in which the passage is divided. The resin stopper may come into contact with the movable body when the movable body is disposed at least at one end of the guide hole.

### Advantageous Effects of Invention

As described above, in the in-line film-forming apparatus according to the invention, immediately before the piston in the cylinder reaches an end in one direction, the flow rate of air through the second valve mechanism is reduced. Immediately before the piston in the cylinder reaches an end in the other direction, the flow rate of air through the first valve mechanism is reduced. In this way, it is possible to prevent the occurrence of vibration due to an operation of opening and closing the gate valve. Therefore, it is possible to prevent scratches from occurring in the substrate held by the carrier and perform the operation of opening and closing the gate valve at a high speed.

In addition, in the method of manufacturing a magnetic recording medium according to the invention, the in-line film-forming apparatus is used. Therefore, it is possible to improve the capability to manufacture a magnetic recording medium and manufacture a high-quality magnetic recording medium.

The gate valve according to the invention can open and close a passage at a high speed while preventing the occurrence of vibration.

### BRIEF DESCRIPTION OF DRAWINGS

FIG. 1 is a cross-sectional view illustrating an example of a magnetic recording medium manufactured by the invention.

FIG. 2 is a cross-sectional view illustrating an example of a magnetic recording/reproducing apparatus.

FIG. 3 is a plan view illustrating the structure of an in-line film-forming apparatus according to the invention.

FIG. 4 is a side view illustrating a carrier of the in-line film-forming apparatus according to the invention.

FIG. 5 is a side view illustrating a main part of the in-line film-forming apparatus according to the invention.

FIG. 6 is a cross-sectional view illustrating a main part of the in-line film-forming apparatus according to the invention.

FIG. 7 is a diagram illustrating the structure and operation of a gate valve and is a cross-sectional view illustrating a state in which a passage is opened by a valve body.

FIG. 8 is a diagram illustrating the structure and operation of the gate valve and is a cross-sectional view illustrating a state in which the valve body faces the passage.

FIG. 9 is a diagram illustrating the structure and operation of the gate valve and is a cross-sectional view illustrating a state in which the valve body blocks the passage.

### DESCRIPTION OF EMBODIMENTS

Hereinafter, an exemplary embodiment of the invention will be described in detail with reference to the accompanying drawings.

In this embodiment, an example in which an in-line film-forming apparatus that performs a film-forming process while sequentially transporting a substrate, which is a deposition target, between a plurality of chambers is used to manufacture a magnetic recording medium to be provided in a hard disk device will be described.

### (Magnetic Recording Medium)

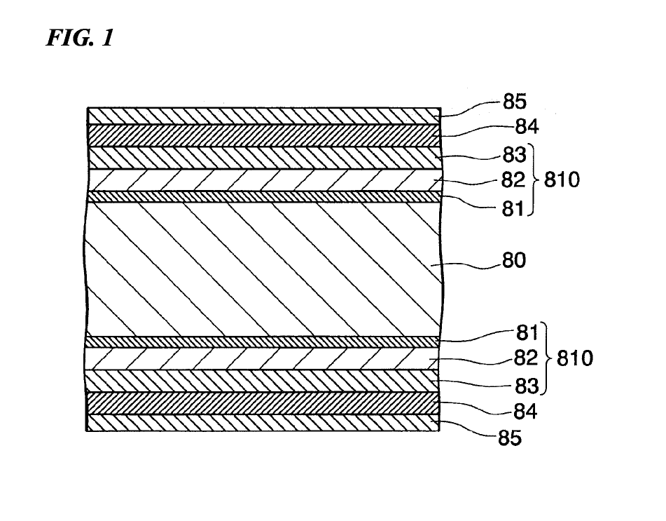

As shown in FIG. 1, for example, a magnetic recording medium manufactured by the invention has a structure in which soft magnetic layers 81, intermediate layers 82, recording magnetic layers 83, and protective layers 84 are sequentially formed on both surfaces of a non-magnetic substrate 80 and lubrication films 85 are further formed on the outermost surfaces. In addition, the soft magnetic layer 81, the intermediate layer 82, and the recording magnetic layer 83 form a magnetic layer 810.

The non-magnetic substrate 80 may be any non-magnetic substrate, such as an Al alloy substrate made of, for example, an Al—Mg alloy having Al as a main component, or a substrate made of general soda glass, aluminosilicate-based glass, crystallized glass, silicon, titanium, ceramics, or various kinds of resins.

Among them, it is preferable to use an Al alloy substrate, a glass substrate made of, for example, crystallized glass, or a silicon substrate. In addition, the average surface roughness (Ra) of the substrate is preferably equal to or less than 1 nm, more preferably equal to or less than 0.5 nm, and most preferably equal to or less than 0.1 nm.

The magnetic layer 810 may be an in-plane magnetic layer for an in-plane magnetic recording medium or a perpendicular magnetic layer for a perpendicular magnetic recording medium. However, it is preferable that the magnetic layer 810 be a perpendicular magnetic layer in order to obtain high recording density. It is preferable that the recording magnetic layer 83 be made of an alloy having Co as a main component. For example, the magnetic layer 810 for a perpendicular magnetic recording medium may be a laminate of the soft magnetic layer 81 made of, for example, a soft magnetic FeCo alloy (for example, FeCoB, FeCoSiB, FeCoZr, FeCoZrB, or FeCoZrBCu), a FeTa alloy (for example, FeTaN or FeTaC), or a Co alloy (for example, CoTaZr, CoZrNB, or CoB), the intermediate layer 82 made of, for example, Ru, and the recording magnetic layer 83 made of a 60Co-15Cr-15Pt alloy or a 70Co-5Cr-15Pt-10SiO₂ alloy. In addition, an orientation control film made of, for example, Pt, Pd, NiCr, or NiFeCr may be formed between the soft magnetic layer 81 and the intermediate layer 82. The magnetic layer 810 for an in-plane magnetic recording medium may be a laminate of a non-magnetic CrMo base layer and a ferromagnetic CoCrPtTa magnetic layer.

The total thickness of the magnetic layer 810 is equal to or greater than 3 nm and equal to or less than 20 nm, and preferably equal to or greater than 5 nm and equal to or less than 15 nm. The magnetic layer 810 may be formed such that sufficient head input and output are obtained according to the kind of magnetic alloy and the laminated structure used. The thickness of the magnetic layer 810 needs to be equal to or greater than a predetermined value in order to obtain an output equal to or greater than a predetermined value during reproduction. In general, various parameters indicating recording and reproduction characteristics deteriorate with an increase in output. Therefore, it is necessary to set the thickness of the magnetic layer 810 to an optimal value.

The protective layer 84 may be made of a carbon-based material, such as carbon (C), hydrogenated carbon (H_{X}C), nitrogenerated carbon (CN), amorphous carbon, or silicon carbide (SiC), or a general protective layer material, such as SiO₂, Zr₂O₃, or TiN. The protective layer 84 may include two or more layers. The thickness of the protective layer 84 needs to be less than 10 nm. When the thickness of the protective layer 84 is more than 10 nm, the distance between the head and the recording magnetic layer 83 is long and it is difficult to obtain the sufficient intensity of output/input signals.

For example, a fluorine-based lubricant, a carbon hydride-based lubricant, and a mixture thereof may be used as the lubricant used in the lubrication film 85. In general, the lubrication layer 85 is formed with a thickness of 1 nm to 4 nm.

### (Magnetic Recording/Reproducing Apparatus)

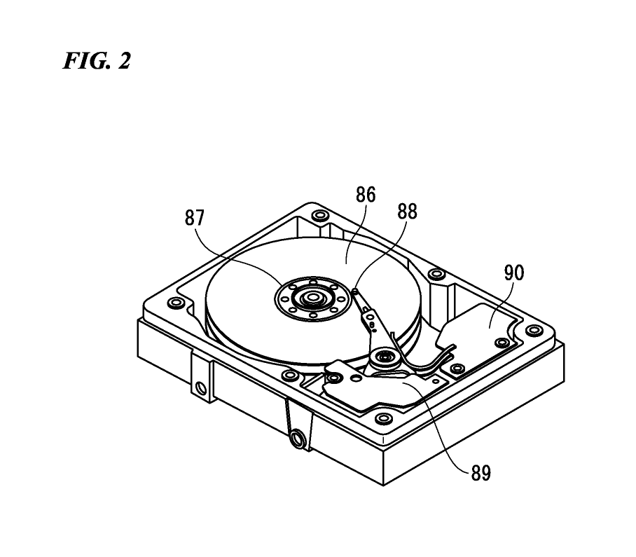

For example, a hard disk device shown in FIG. 2 may be used as a magnetic recording/reproducing device using the magnetic recording medium. The hard disk device includes a magnetic disk 86, which is a magnetic recording medium, a medium driving unit 87 that rotates the magnetic disk 86, a magnetic head 88 that records and reproduces information on and from the magnetic disk 86, a head driving unit 89, and a recording/reproduction signal processing system 90. The magnetic reproduction signal processing system 90 processes input data, transmits a recording signal to the magnetic head 88, processes a reproduction signal from the magnetic head 88, and outputs data.

### (In-Line Film-Forming Apparatus)

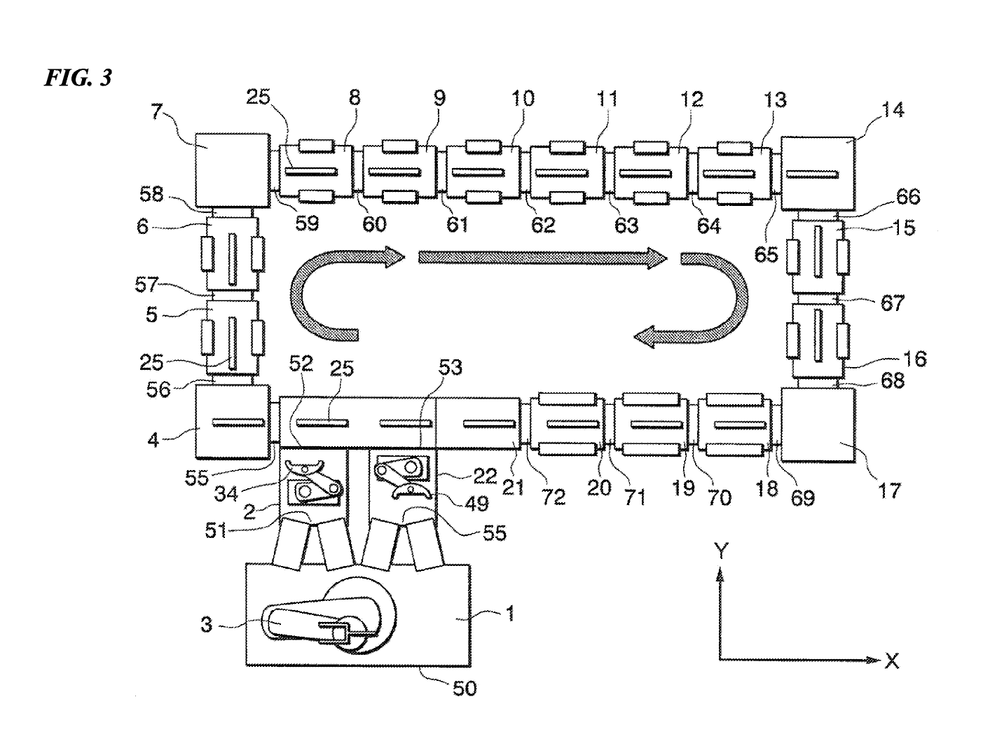

Specifically, when the magnetic recording medium is manufactured, for example, an in-line film-forming apparatus (apparatus for manufacturing the magnetic recording medium) according to the invention shown in FIG. 3 is used to stably obtain a high-quality magnetic recording medium through a process of sequentially forming at least the soft magnetic layers 81, the intermediate layers 82, the recording magnetic layers 83, and the protective layers on both surfaces of the non-magnetic substrate 80, which is a deposition target, thereby forming the magnetic layers 810 and a process of forming the protective layers 84.

Specifically, the in-line film-forming apparatus according to the invention includes a robot stand 1, a substrate-moving robot 3 that is mounted on the robot stand 1, a substrate supply robot chamber 2 adjacent to the robot stand 1, a substrate supply robot 34 that is provided in the substrate supply robot chamber 2, a substrate attachment chamber 52 adjacent to the substrate supply robot chamber 2, corner chambers 4, 7, 14, and 17 that rotate a carrier 25, a plurality of chambers 5, 6, 8 to 13, 15, 16, and 18 to 21 that are provided between the corner chambers 4, 7, 14, and 17, a substrate removal chamber 53 that is provided adjacent to the chamber 21, a substrate removal robot chamber 22 that is provided adjacent to a substrate removal chamber 53, and a substrate removal robot 49 that is provided in the substrate removal robot chamber 22.

Gate valves 55 to 72 are provided in connection portions between the chambers. When the gate valves 55 to 72 are closed, the inside of each chamber is an independent closed space. The soft magnetic layer 81, the intermediate layer 82, the recording magnetic layer 83, and the protective layer 84 are sequentially formed on both surfaces of the non-magnetic substrate 80 held by the carrier 25 in the chambers 5, 6, 8 to 13, 15, 16, and 18 to 21 while the carrier 25 is sequentially transported between the chambers by a transport mechanism, which will be described below. Finally, the magnetic recording medium shown in FIG. 1 is obtained. Each of the corner chambers 4, 7, 14, and 17 changes the moving direction of the carrier 25 and includes a mechanism that rotates the carrier 25 and moves it to the next chamber.

The substrate-moving robot 3 supplies the non-magnetic substrate 80 from a cassette in which the non-magnetic substrates 80 before deposition are accommodated to the substrate attachment chamber 2 and takes outs the non-magnetic substrate 80 (magnetic recording medium) after deposition which is removed from the substrate removal robot chamber 22. Doors 51 and 55 that open or close openings exposed to the outside are provided in one side wall of each of the substrate attachment chamber 2 and the substrate removal robot chamber 22.

In the substrate attachment chamber 52, the non-magnetic substrate 80 before deposition is held on the carrier 25 by the substrate supply robot 34. In the substrate removal chamber 53, the non-magnetic substrate 80 (magnetic recording medium) after deposition held on the carrier 25 is removed by the substrate removal robot 49.

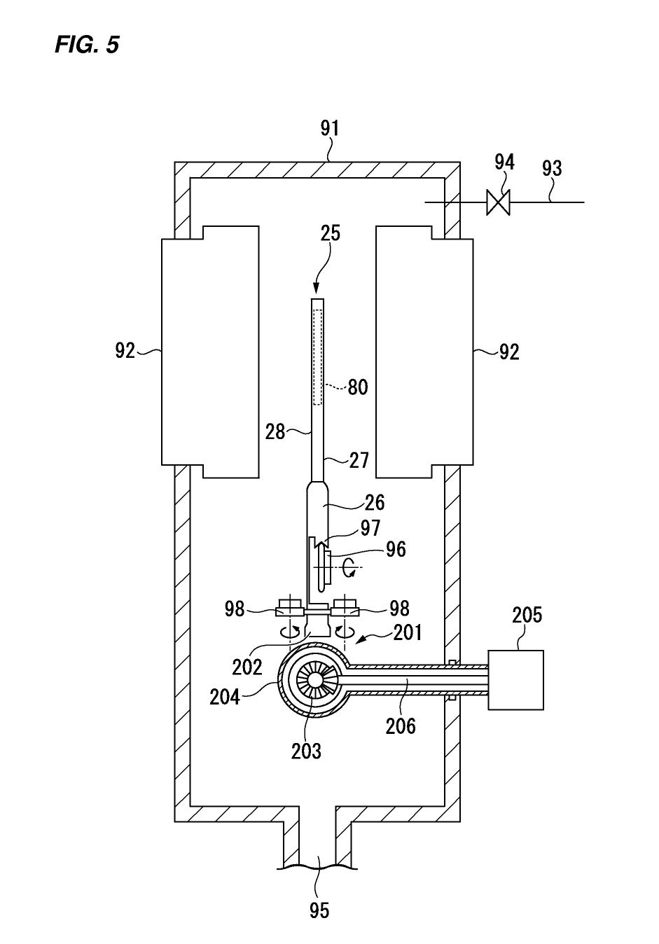

The chambers 5, 6, 8 to 13, 15, 16, and 18 to 21 that perform a film-forming process for manufacturing the magnetic recording medium have the same basic structure except that the structures of processing devices are different from each other according to the content of processes. Therefore, the structure of a chamber 91 shown in FIG. 5 will be described as a representative example of the structure of the chambers.

As shown in FIG. 5, two processing devices 92 that perform a film-forming process on the non-magnetic substrate 80 held by the carrier 25 are arranged in the chamber 91 so as to be opposite to each other with the carrier 25 interposed therebetween.

For example, when the film-forming process is performed by sputtering, the two processing devices 92 include a cathode unit for generating a sputtering discharge. When the film-forming process is performed by a CVD method, the two processing devices 92 include an electrode unit for forming a film-forming space for the CVD method. When the film-forming process is performed by a PVD method, the two processing devices 92 include an ion gun.

A gas introduction pipe 93 for introducing a raw material gas or an atmosphere gas is provided in the chamber 91. The gas introduction pipe 93 includes a valve 94 whose opening and closing are controlled by a control mechanism (not shown). The valve 94 is opened and closed to control the supply of gas from the gas introduction pipe 93.

A gas exhaust pipe 95 connected to a vacuum pump (not shown) is provided in the chamber 91. The inside of the chamber 91 can be evacuated through the gas exhaust pipe 95 connected to the vacuum pump.

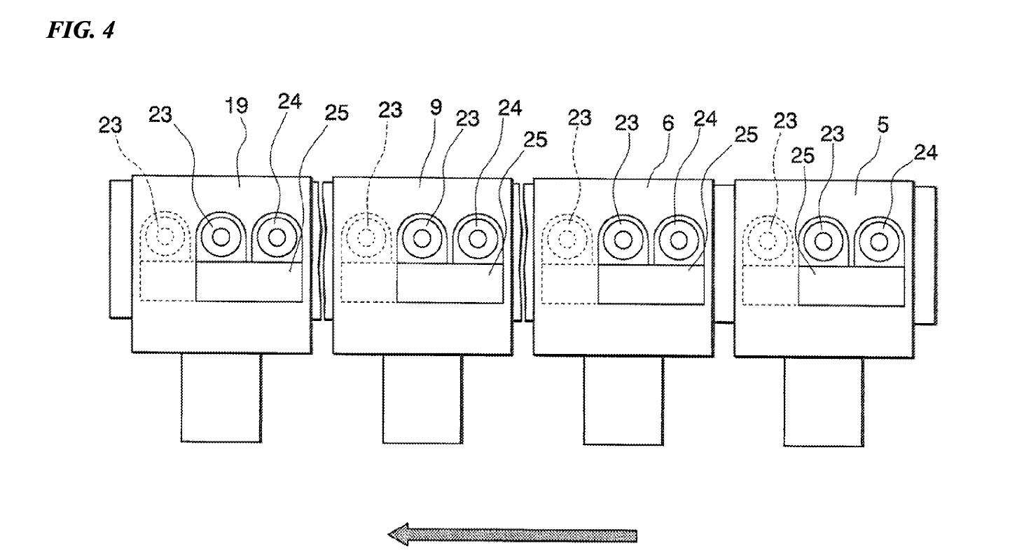

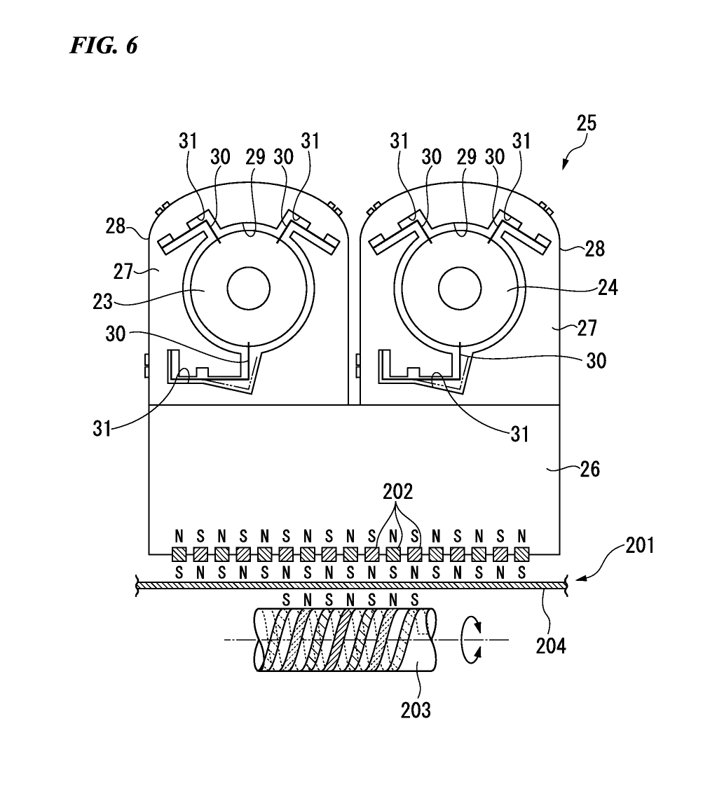

As shown in FIGS. 4 and 6, the carrier 25 includes a support 26 and a plurality of holders 27 which are provided on the upper surface of the support 26. In this embodiment, since two holders 27 are provided, two non-magnetic substrates 80 held by the holders 27 are treated as a first film-forming substrate 23 and a second film-forming substrate 24.

In this embodiment, for example, with the carrier 25 stopped at a first processing position represented by a solid line in FIG. 4, two processing devices 91 can perform the film-forming process on both surfaces of the first film-forming substrate 23 on the left side of the carrier 25 and the carrier 25 can be moved to a second processing position represented by a dashed line in FIG. 5. With the carrier 25 stopped at the second processing position, the two processing devices 91 can perform the film-forming process on both surfaces of the second film-forming substrate 24 on the right side of the carrier 25.

When four processing devices 92 facing the first and second film-forming substrates 23 and 24 are provided on both sides of the carrier 25 so as to be opposite to each other with the carrier 25 interposed therebetween, the movement of the carrier 25 is not needed, and the film-forming process can be simultaneously performed on the first and second film-forming substrates 23 and 24 held by the carrier 25.

The two holders 27 are provided in parallel on the upper surface of the support 26 such that the first and twentieth film-forming substrates 23 and 24 are vertically held (in a state in which the main surfaces of the substrates 23 and 24 are parallel to the gravity direction), that is, the main surfaces of the first and second film-forming substrates 23 and 24 are substantially perpendicular to the upper surface of the support 26 and are substantially on the same plane.

In each of the holders 27, a circular hole portion 29 with a diameter that is slightly more than the outside diameter of the first and second film-forming substrates 23 and 24 is formed in a plate 28 with a thickness that is equal to or several times more than the thickness of the first and second film-forming substrates 23 and 24.

A plurality of supporting members 30 are attached around the hole portion 29 of each holder 27 so as to be elastically deformable. Three supporting members 30 are provided at predetermined intervals around the hole portion 29 of the holder 27 such that the outer circumference of each of the first and second film-forming substrates 23 and 24 arranged inside the hole portions 29 are supported by three points, that is, a lower supporting point that is disposed at the lowest position on the outer circumference and a pair of upper supporting points that are disposed at the upper positions on the outer circumference and are symmetric with respect to a center line which passes through the lower supporting point and is along the gravity direction.

In this way, in the carrier 25, the holders 27 can removably hold the first and second film-forming substrates 23 and 24 inserted into the supporting members 30 while the three supporting members 30 come into contact with the outer circumferences of the first and second film-forming substrates 23 and 24. In addition, the substrate supply robot 34 or the substrate removal robot 49 presses the supporting member 30 at the lower supporting point downward to insert or remove the first and second film-forming substrates 23 and 24 into or from the holder 27.

As shown in FIG. 6, each supporting member 30 is a spring member which is bent in an L shape and is arranged in a slit 31 which is formed around the hole portion 29 of the holder 27 while the base end thereof is fixed and supported by the holder 27 and the leading end thereof protrudes toward the inside of the hole portion 29. In addition, A V-shaped groove (not shown) to which the outer circumference of each of the first and second film-forming substrates 23 and 24 is fitted is provided at the leading end of each supporting member 30.

As shown in FIGS. 5 and 6, the in-line film-forming apparatus includes a driving mechanism 201 that drives the carrier 25 in a non-contact manner as the transport mechanism for transporting the carrier 25.

The driving mechanism 201 includes a plurality of magnets 202 which are provided below the carrier 25 such that the N poles and the S poles are alternately arranged and a rotary magnet 203 which is arranged below the magnets 202 along the transport direction of the carrier 25. The N poles and the S poles are alternately arranged in a double spiral shape on the outer circumferential surface of the rotary magnet 203.

A vacuum partition wall 204 is interposed between the plurality of magnets 202 and the rotary magnet 203. The vacuum partition wall 204 is made of a material with high magnetic permeability such that the plurality of magnets 202 are magnetically coupled to the rotary magnet 203. In addition, the vacuum partition wall 204 surrounds the rotary magnet 203 to isolate the inside of the chamber 91 from air.

The rotary magnet 203 is connected to a rotating shaft 206 rotated by the rotary motor 205 through a plurality of gears which are engaged with each other. In this way, it is possible to rotate the rotary magnet 203 on its own axis while transmitting the driving force of the rotary motor 205 to the rotary magnet 203 through the rotating shaft 206.

The driving mechanism 201 having the above-mentioned structure rotates the rotary magnet 203 on its own axis while magnetically coupling the magnets 202 of the carrier 25 with the rotary magnet 203 in a non-contact manner, thereby driving the carrier 25 in a straight line along the axial direction of the rotary magnet 203.

In addition, as a guide mechanism which guides the transported carrier 25, a plurality of main bearings 96 which are supported so as to be rotatable on the horizontal axis are provided in the transport direction of the carrier 25 in the chamber 91. The carrier 25 includes a guide rail 97 which is provided at a lower part of the support 26 and to which the plurality of main bearings 96 are fitted. A V-shaped groove is formed in the guide rail 97 in the longitudinal direction of the support 26.

In addition, a pair of sub-bearings 98 which are supported so as to be rotatable on the vertical axis are provided in the chamber 91 so as to have the carrier 25 interposed therebetween. Similarly to the plurality of main bearings 96, the pair of sub-bearings 98 are provided in the transport direction of the carrier 25.

The main bearing 96 and the sub-bearing 98 are bearings for reducing the friction of machine components and ensuring the smooth rotation of the machine, particularly, ball bearings, and are rotatably attached to a supporting shaft (not shown in FIG. 5) which is fixed to a frame (attachment member) provided in the chamber 91.

The carrier 25 is moved on the plurality of main bearings 96 fitted to the guide rail 97 and is interposed between the pair of sub-bearings 98. In this way, the inclination of the carrier 25 is prevented.

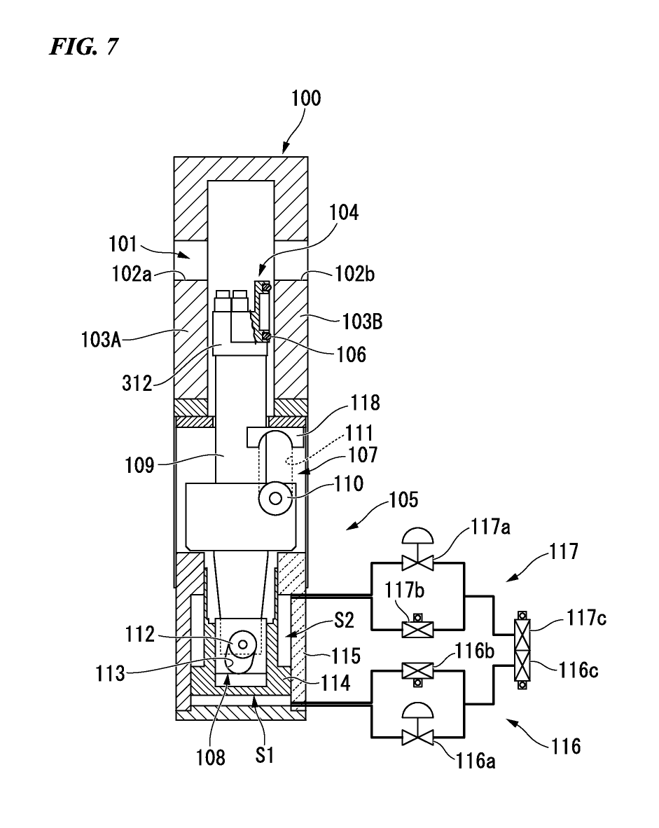

The in-line film-forming apparatus according to the invention includes a gate valve 100 shown in FIGS. 7 to 9. Since the gate valves 55 to 72 have the same basic structure as the gate valve 100, the structure of the gate valve 100 will be described as a representative example of the detailed structure of the gate valves 55 to 72. FIGS. 7 to 9 are cross-sectional views illustrating the gate valve 100, as viewed from the upper side.

The gate valve 100 includes a pair of partition walls 103A and 103B in which opening portions 102a and 102b forming a passage 101 through which the carrier 25 passes are formed, a valve body 104 which is moved and operated between the pair of partition walls 103A and 103B, and a driving mechanism 105 which drives the valve body 104 between a position where the opening portion 102b is closed and a position where the opening portion 102b is opened.

The valve body 104 is a plate member which is formed in a substantially rectangular shape with a sufficient size to block the opening portion 102b. A sealing member 106 which is pressed against the partition wall 103B at a position where it surrounds the opening portion 102b is provided in the surface of the valve body 104 facing the opening portion 102b.

The sealing member 106 is an O-ring obtained by forming an elastic member made of rubber, such as fluorine-contained rubber, or resin into a ring shape. The sealing member 106 is attached so as to be fitted to a groove which is provided in the surface of the valve body 104 facing the opening portion 102b. In addition, the sealing member 106 is arranged such that a portion thereof protrudes toward the outside of the groove.

The gate valve 100 includes a guide mechanism 107 that guides the valve body 104 so as to be movable in a direction in which the passage 101 is divided and a cam mechanism 108 that guides the valve body 104 so as to be inclined in a direction in which the valve body 104 can come into contact with or be separated from the partition wall 103B at a position where it faces the opening portion 102b.

Specifically, the valve body 104 is attached to the leading end of an arm 109 which extends in the direction in which the passage 101 is divided, while being perpendicular to the arm 107 (in a so-called T shape).

The guide mechanism 107 includes a guide plate (movable body) 110 that is provided in the middle of the arm 109 and is moved integrally with the valve body 104 and a guide hole 111 to which the guide plate 110 is fitted. The guide plate 110 is moved in the guide hole 111 to guide the valve body 104 in the direction in which the passage 101 is divided.

The cam mechanism 108 includes a cam plate (movable body) 112 that is provided at the base end of the arm 109 and is moved integrally with the valve body 104 and a cam hole 113 to which the cam plate 112 is fitted. The cam plate 112 is moved in the cam hole 113 to guide the valve body 104 so as to be inclined in the direction in which it can come into contact with or be separated from the partition wall 103B.

The driving mechanism 105 is an air cylinder mechanism that uses air pressure as a driving force and includes a piston 114 that is connected to the base end of the arm 107, a cylinder 115 that is provided in the piston 114, a first valve mechanism 116 including a first on-off valve 116a and a first flow rate-adjusting valve 116b that are connected in parallel to a first space S1 in the cylinder 115, a switching valve 116c for switching between the supply and exhaust of air to and from the first on-off valve 116a and the first flow rate-adjusting valve 116b, a second valve mechanism 117 including a second on-off valve 117a and a second flow rate-adjusting valve 117b that are connected in parallel to a second space S2 in the cylinder 115, and a switching valve 117c for switching between the supply and exhaust of air to and from the second on-off valve 117a and the second flow rate-adjusting valve 117b.

Specifically, the first space 51 is opposite to the valve body 104 with the piston 114 interposed therebetween (the lower side of FIGS. 7 to 9) in the cylinder 115 and the second space S2 is closer to the valve body 104 (the upper side of FIGS. 7 to 9) than the piston 114 in the cylinder 115. Electromagnetic valves only for the opening and closing of a flow path are used as the first and second on-off valves 116a and 117a, and needle valves which can adjust the flow rate of air through a flow path in addition to the opening and closing of the flow path are used as the first and second flow rate-adjusting valves 116b and 117b.

In the gate valve 100 having the above-mentioned structure, as shown in FIG. 7, with the opening portion 102b of the passage 101 opened, the driving mechanism 105 moves the valve body 104 to one side (the upper side of FIGS. 7 to 9) in the direction in which the passage 101 is divided.

In this case, the driving mechanism 105 exhausts air in the second space S2 from the second switching valve 117c through the second on-off valve 117a, the second flow rate-adjusting valve 117b while supplying air from the first switching valve 116c to the first space 51 through the first on-off valve 116a and the first flow rate-adjusting valve 116b, thereby pressing and moving the piston 114 in the cylinder 115 in one direction (the upper side of FIGS. 7 to 9).

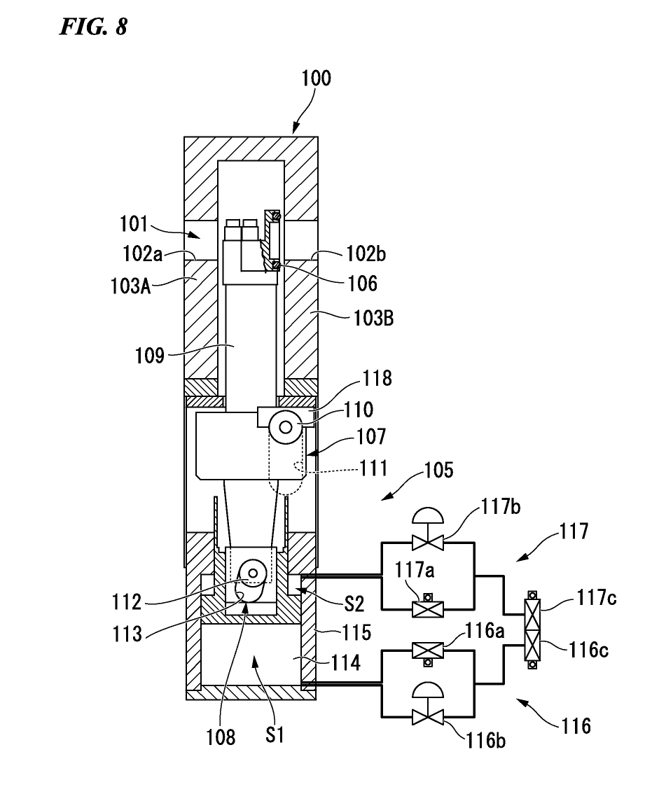

Then, as shown in FIG. 8, the valve body 104 is moved to the position where it faces the opening portion 102b of the partition wall 103B while being guided by the guide mechanism 107. Then, the driving mechanism 105 further moves the piston 114 of the cylinder 115 in one direction (the upper side of FIGS. 7 to 9).

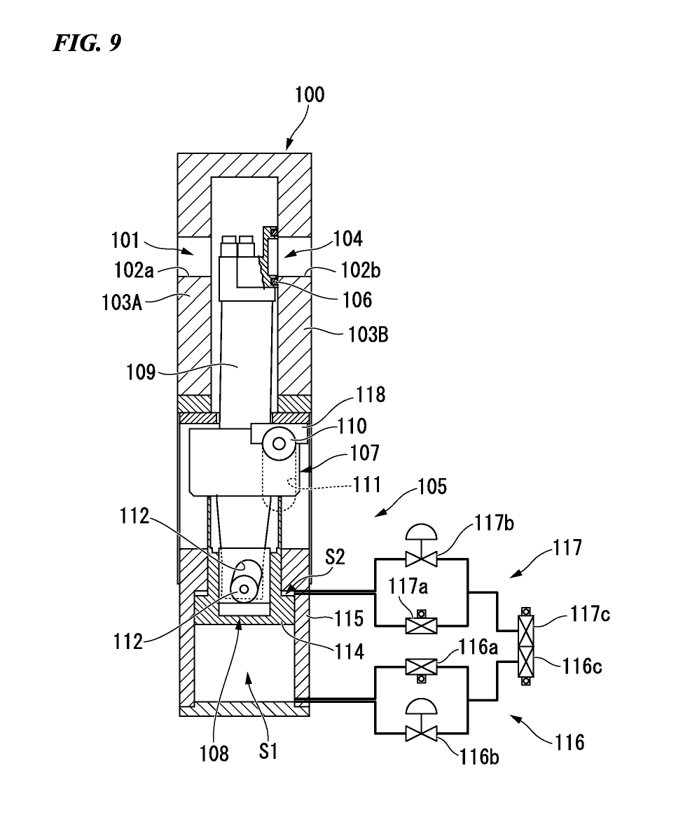

Then, as shown in FIG. 9, the valve body 104 is inclined in a direction in which it approaches the partition wall 103B while being guided by the cam mechanism 108. Finally, the valve body 104 blocks the opening portion 102b with the sealing member 105 coming into pressure contact with the partition wall 103B.

In this way, in the in-line film-forming apparatus, it is possible to block the passages 101 provided between two chambers connected to the gate valve 100. In addition, it is possible to perform an operation (process closing operation) of closing the gate valve 100 in order to independently maintain the pressures of the chambers and an operation (atmospheric closing operation) of closing the gate valve 100 in order to isolate atmosphere from a vacuum during maintenance.

The gate valve 100 can operate reversely to the above to open the passage 101. That is, in the gate valve 100, as shown in FIG. 9, with the opening portion 102b of the passage 101 blocked by the valve body 104, the driving mechanism 105 moves the valve body 104 in the other side (the lower side of FIGS. 7 to 9) in the direction in which the passage 101 is divided.

In this case, the driving mechanism 105 exhausts air in the first space 51 from the first switching valve 116c through the first on-off valve 116a and the first flow rate-adjusting valve 116b while supplying air from the second switching valve 117c to the second space S2 through the second on-off valve 117a and the second flow rate-adjusting valve 117b, thereby pressing and moving the piston 114 in the cylinder 115 in the other direction (the lower side of FIGS. 7 to 9) in which the valve body 104 opens the opening portion 102b.

Then, as shown in FIG. 8, the valve body 104 is inclined in the direction in which it is separated from the partition wall 103B and is moved to the position where it faces the opening portion 102b of the partition wall 103B, while being guided by the cam mechanism 108. Then, the driving mechanism 105 further presses and moves the piston 114 in the cylinder 115 in the other direction (the lower side of FIGS. 7 to 9).

Then, as shown in FIG. 7, the valve body 104 is moved in the other side (the lower side of FIGS. 7 to 9) in the direction in which the passage 101 is divided, while being guided by the guide mechanism 107. Finally, the valve body 104 is moved to the position where it opens the opening portion 102b of the partition wall 103B.

In this way, in the in-line film-forming apparatus, when the carrier 25 is transported, it is possible to open the passages 101 provided in two chambers which are connected through the gate valve 100. Two gate valves 100 may be provided between the chambers and similarly open and close the opening portion 102a provided in another partition wall 103A.

However, in the gate valve 100 according to the invention, when the passage 101 is blocked by the valve body 104, the second on-off valve 117a is completely closed immediately before the piston 114 in the cylinder 115 reaches the end in one direction (one end), and air is exhausted only by the second flow rate-adjusting valve 117b. In this way, it is possible to prevent vibration caused by the contact between the one end of the cylinder 115 and the piston 114 when the piston 114 in the cylinder 115 reaches the one end.

That is, in the driving mechanism 5, immediately before the piston 114 in the cylinder 115 reaches one end, the second valve mechanism 117 reduces the flow rate of air exhausted from the second space S2 in the cylinder 115. In this way, the exhaust resistance of the piston 114 in one direction in the cylinder 115 increases. The exhaust resistance functions as a so-called air cushion and reduces impact due to the contact between one end of the cylinder 115 and the piston 114. Therefore, it is possible to prevent the occurrence of vibration.

In the gate valve 100 according to the invention, when the passage 101 is opened by the valve body 104, similarly, the first on-off valve 116a is completely closed immediately before the piston 114 in the cylinder 115 reaches the end in the other direction (the other end), and air is exhausted only by the first flow rate-adjusting valve 116b. In this way, it is possible to prevent vibration caused by the contact between the other end of the cylinder 115 and the piston 114 when the piston 114 in the cylinder 115 reaches the other end.

That is, in the driving mechanism 5, immediately before the piston 114 in the cylinder 115 reaches the other end, the first valve mechanism 116 reduces the flow rate of air exhausted from the first space S1 in the cylinder 115. In this way, the exhaust resistance of the piston 114 in the other direction in the cylinder 115 increases. The exhaust resistance functions as a so-called air cushion and reduces impact due to the contact between the other end of the cylinder 115 and the piston 114. Therefore, it is possible to prevent the occurrence of vibration.

In addition, the guide mechanism 107 includes a resin stopper 118 that comes into contact with the guide plate 110 when the guide plate 110 is disposed at one end of the guide hole 111.

In this case, the resin stopper 118 reduces impact due to the contact between the guide plate 110 and one end of the guide hole 111, and it is possible to prevent the occurrence of vibration when the piston 114 in the cylinder 115 reaches the upper end.

The resin stopper 118 may be provided at the other end of the guide hole 111, instead of the one end of the guide hole 111. In this case, the resin stopper 118 reduces impact due to the contact between the guide plate 110 and the other end of the guide hole 111, and it is possible to prevent the occurrence of vibration when the piston 114 in the cylinder 115 reaches the other end.

In the invention, the weight of a movable portion of the driving mechanism 5 is reduced. Therefore, it is possible to further reduce the occurrence of vibration due to an operation of opening and closing the gate valve 100.

As described above, in the in-line film-forming apparatus according to the invention, it is possible to perform an operation of opening and closing the passage 101 through which the carrier 25 passes using the gate valve 100 at a high speed. In addition, it is possible to prevent, for example, the occurrence of vibration when the gate valve 100 opens and closes the passage 101. Therefore, it is possible to prevent the occurrence of scratches on the non-magnetic substrate 80 held by the carrier 25.

The invention is not necessarily limited to the above-described embodiment, but various modifications and changes to the invention can be made without departing from the scope and spirit of the invention.

That is, in the invention, immediately before the piston 114 in the cylinder 115 reaches the end in one direction, the second valve mechanism 117 may reduce the flow rate of air exhausted from the second space S2. Immediately before the piston 114 in the cylinder 115 reaches the end in the other direction, the first valve mechanism 116 may reduce the flow rate of air exhausted from the first space S1.

For example, in the invention, among the first on-off valve 116a and the first flow rate-adjusting valve 116b forming the first valve mechanism 116 and the second on-off valve 117a and the second flow rate-adjusting valve 117b forming the second valve mechanism 117, the first and second on-off valves 116a and 117a may be omitted. Immediately before the piston 114 in the cylinder 115 reaches the end in one direction, the second flow rate-adjusting valve 117b may reduce the flow rate of air exhausted from the second space S2. Immediately before the piston 114 in the cylinder 115 reaches the end in the other direction, the first flow rate-adjusting valve 116b may reduce the flow rate of air exhausted from the first space S1.

### (Method of Manufacturing Magnetic Recording Medium)

In a method of manufacturing the magnetic recording medium according to the invention, the in-line film-forming apparatus is used to sequentially form the magnetic layers 810, each having the soft magnetic layer 81, the intermediate layer 82, and the recording magnetic layer 83, and the protective layers 84 on both surfaces of the non-magnetic substrate 80 while sequentially transporting the first or second film-forming substrate 23 or 24 (non-magnetic substrate 80) held by the carrier 25 between a plurality of chambers 2, 52, 4 to 20, 54, and 3A, and is used to further form the lubrication films 85 on the outermost surfaces, thereby manufacturing a magnetic recording medium.

In the method of manufacturing the magnetic recording medium according to the invention, the in-line film-forming apparatus is used. Therefore, it is possible to improve the manufacturing capability of the magnetic recording medium 80 and manufacture the high-quality magnetic recording medium 80.

### EXAMPLES

Next, the effect of the invention will be clearly described with reference to examples. The invention is not limited to the following examples, but various modifications and changes to the invention can be made without departing from the scope and spirit of the invention.

In an example, the gate valve 100 shown in FIGS. 7 to 9 was actually used, and during an operation of opening and closing the passage 101 through which the carrier 25 passed, vibration caused by an operation of opening and closing the gate valve 100 was measured when the second or first on-off valve 117a or 116a was completely closed and air was exhausted by the second or first flow rate-adjusting valve 117b or 116b immediately before the piston 114 in the cylinder 115 reached one end or the other end, as in the invention (Example 1), and when the opening and closing operation was not performed immediately before the piston 114 in the cylinder 115 reached one end or the other end, as in the related art (Comparative example 1).

In this example, an acceleration sensor (PV-93B manufactured by Rion Co., Ltd.) was attached to the bottom of the cylinder 115 of the gate valve 100 and a digital oscillo-recorder (RA1300 RT3214 manufactured NEC Sanei Corporation) was used to measure vibration (maximum acceleration) caused by the operation of opening and closing the gate valve 100. In addition, the time required for the operation of opening (or closing) the gate valve 100 was adjusted on the basis of gas pressure applied to the gate valve 100.

### Example 1

In Example 1, the maximum acceleration of the gate valve 100 during the operation of closing the gate valve 100 was 2.8 m/s² at an operation speed of 0.35 sec, 2.9 m/s² at an operation speed of 0.31 sec, and 5.5 m/s² at an operation speed of 0.25 sec. On the other hand, the maximum acceleration of the gate valve 100 during the operation of opening the gate valve 100 was 2.1 m/s² at an operation speed of 0.45 sec, 3.4 m/s² at an operation speed of 0.29 sec, and 4.0 m/s² at an operation speed of 0.27 sec.

### Comparative Example 1

In Comparative example 1, the maximum acceleration of the gate valve 100 during the operation of closing the gate valve 100 was 4.2 m/s² at an operation speed of 0.35 sec, 7.2 m/s² at an operation speed of 0.31 sec, and 8.0 m/s² at an operation speed of 0.25 sec. On the other hand, the maximum acceleration of the gate valve 100 during the operation of opening the gate valve 100 was 2.1 m/s² at an operation speed of 0.45 sec, 4.3 m/s² at an operation speed of 0.29 sec, and 7.8 m/s² at an operation speed of 0.27 sec.

As described above, when the operation of reducing the flow rate according to the invention was performed, it was possible to significantly reduce vibration caused by the operation of opening and closing the gate valve, as compared to the related art in which the operation of reducing the flow rate according to the invention was not performed.

### INDUSTRIAL APPLICABILITY

The invention can be applied to an in-line film-forming apparatus that performs a film-forming process while sequentially transporting a substrate, which is a deposition target, between a plurality of chambers, a method of manufacturing a magnetic recording medium using the in-line film-forming apparatus, and a gate valve that opens and closes a passage between a plurality of chambers of the in-line film-forming apparatus.

### REFERENCE SIGNS LIST

1: SUBSTRATE-MOVING ROBOT STAND
2: SUBSTRATE SUPPLY ROBOT CHAMBER
3: SUBSTRATE CASSETTE MOVING ROBOT
4, 7, 14, 17: CORNER CHAMBER
5, 6, 8 TO 13, 15, 16, 18 TO 21: CHAMBER
22: SUBSTRATE REMOVAL ROBOT CHAMBER
23: FIRST FILM-FORMING SUBSTRATE
24: SECOND FILM-FORMING SUBSTRATE
25: CARRIER
26: SUPPORT
27: HOLDER
28: PLATE
29: CIRCULAR HOLE PORTION
30: SUPPORTING MEMBER
34: SUBSTRATE SUPPLY ROBOT
49: SUBSTRATE REMOVAL ROBOT
52: SUBSTRATE ATTACHMENT CHAMBER
54: SUBSTRATE REMOVAL CHAMBER
55 TO 71: GATE VALVE
80: NON-MAGNETIC SUBSTRATE
81: SOFT MAGNETIC LAYER
82: INTERMEDIATE LAYER
83: RECORDING MAGNETIC LAYER
84: PROTECTIVE LAYER
85: LUBRICATION FILM
91: CHAMBER
810: MAGNETIC LAYER
100: GATE VALVE
101: PASSAGE
102a, 102b: OPENING PORTION
103A, 103B: PARTITION WALL
104: VALVE BODY
105: DRIVING MECHANISM (AIR CYLINDER MECHANISM)
106: SEALING MEMBER
107: GUIDE MECHANISM
108: CAM MECHANISM
109: ARM
110: GUIDE PLATE (MOVABLE BODY)
111: GUIDE HOLE
112: GUIDE PLATE (MOVABLE BODY)
113: CAM HOLE
114: PISTON
115: CYLINDER
116: FIRST VALVE MECHANISM
116a: FIRST ON-OFF VALVE
116b: FIRST FLOW RATE-ADJUSTING VALVE
116c: FIRST SWITCHING VALVE
117: SECOND VALVE MECHANISM
117a: SECOND ON-OFF VALVE
117b: SECOND FLOW RATE-ADJUSTING VALVE
117c: SECOND SWITCHING VALVE
118: RESIN STOPPER
201: DRIVING MECHANISM (TRANSPORT MECHANISM)
202: MAGNET
203: ROTARY MAGNET
204: VACUUM PARTITION WALL
205: ROTARY MOTOR
206: ROTATING SHAFT

1. An in-line film-forming apparatus comprising:
a plurality of chambers in which a film-forming process is performed;
a carrier that holds a substrate, which is a deposition target, in the plurality of chambers;
a transport mechanism that sequentially transports the carrier between the plurality of chambers; and
a gate valve that is provided between the plurality of chambers and opens and closes a passage through which the carrier passes,
wherein the gate valve includes a pair of partition walls in which opening portions forming the passage are provided, a valve body that is moved and operated between the pair of partition walls, and a driving mechanism that drives the valve body between a position where the opening portion is blocked and a position where the opening portion is opened,
the driving mechanism is an air cylinder mechanism and includes a piston that is connected to the valve body, a cylinder in which the piston is arranged, a first valve mechanism that is connected to a first space in the cylinder, and a second valve mechanism that is connected to a second space in the cylinder,
in the air cylinder mechanism, air is exhausted from the second space through the second valve mechanism while being supplied to the first space through the first valve mechanism, thereby pressing and moving the piston in the cylinder in one direction in which the valve body blocks the opening portion,
in the air cylinder mechanism, air is exhausted from the first space through the first valve mechanism while being supplied to the second space through the second valve mechanism, thereby pressing and moving the piston in the cylinder in the other direction in which the valve body opens the opening portion,
the air cylinder mechanism reduces the flow rate of air exhausted from the second space by the second valve mechanism immediately before the piston in the cylinder reaches an end in the one direction, and
the air cylinder mechanism reduces the flow rate of air exhausted from the first space by the first valve mechanism immediately before the piston in the cylinder reaches an end in the other direction.

2. The in-line film-forming apparatus according to claim 1,
wherein the first valve mechanism includes a first on-off valve and a first flow rate-adjusting valve that are connected in parallel to the first space in the cylinder,
the second valve mechanism includes a second on-off valve and a second flow rate-adjusting valve that are connected in parallel to the second space in the cylinder,
the air cylinder mechanism exhausts air from the second space through the second on-off valve and the second flow rate-adjusting valve while supplying air to the first space through the first on-off valve and the first flow rate-adjusting valve, thereby pressing and moving the piston in the cylinder in the one direction in which the valve body blocks the opening portion such that the second on-off valve is completely closed and air is exhausted only by the second flow rate-adjusting valve immediately before the piston reaches the end in the one direction, and
the air cylinder mechanism exhausts air from the first space through the first on-off valve and the first flow rate-adjusting valve while supplying air to the second space through the second on-off valve and the second flow rate-adjusting valve, thereby pressing and moving the piston in the cylinder in the other direction in which the valve body opens the opening portion such that the first on-off valve is completely closed and air is exhausted only by the first flow rate-adjusting valve immediately before the piston reaches the end in the other direction.

3. The in-line film-forming apparatus according to claim 2,
wherein the first and second on-off valves are electromagnetic valves, and
the first and second flow rate-adjusting valves are needle valves.

4. The in-line film-forming apparatus according to claim 2, further comprising:
a guide mechanism that includes a movable body which is moved integrally with the valve body, a guide hole to which the movable body is fitted, and a resin stopper,
wherein the movable body is moved in the guide hole to guide the valve body such that the valve body can be moved in a direction in which the passage is divided, and
the resin stopper comes into contact with the movable body when the movable body is disposed at least at one end of the guide hole.

5. A method of manufacturing a magnetic recording medium, comprising:
a step of forming at least a magnetic layer on a surface of a substrate using the in-line film-forming apparatus according to claim 1.

6. A gate valve that opens and closes a passage between a plurality of chambers, comprising:
a pair of partition walls in which opening portions forming the passage are provided;
a valve body that is moved and operated between the pair of partition walls; and
a driving mechanism that drives the valve body between a position where the opening portion is blocked and a position where the opening portion is opened,
wherein the driving mechanism is an air cylinder mechanism and includes a piston that is connected to the valve body, a cylinder in which the piston is arranged, a first valve mechanism that is connected to a first space in the cylinder, and a second valve mechanism that is connected to a second space in the cylinder,
in the air cylinder mechanism, air is exhausted from the second space through the second valve mechanism while being supplied to the first space through the first valve mechanism, thereby pressing and moving the piston in the cylinder in one direction in which the valve body blocks the opening portion,
in the air cylinder mechanism, air is exhausted from the first space through the first valve mechanism while being supplied to the second space through the second valve mechanism, thereby pressing and moving the piston in the cylinder in the other direction in which the valve body opens the opening portion,
the air cylinder mechanism reduces the flow rate of air exhausted from the second space by the second valve mechanism immediately before the piston in the cylinder reaches an end in the one direction, and
the air cylinder mechanism reduces the flow rate of air exhausted from the first space by the first valve mechanism immediately before the piston in the cylinder reaches an end in the other direction.

7. The gate valve according to claim 6,
wherein the first valve mechanism includes a first on-off valve and a first flow rate-adjusting valve that are connected in parallel to the first space in the cylinder,
the second valve mechanism includes a second on-off valve and a second flow rate-adjusting valve that are connected in parallel to the second space in the cylinder,
the air cylinder mechanism exhausts air from the second space through the second on-off valve and the second flow rate-adjusting valve while supplying air to the first space through the first on-off valve and the first flow rate-adjusting valve, thereby pressing and moving the piston in the cylinder in the one direction in which the valve body blocks the opening portion such that the second on-off valve is completely closed and air is exhausted only by the second flow rate-adjusting valve immediately before the piston reaches the end in the one direction, and
the air cylinder mechanism exhausts air from the first space through the first on-off valve and the first flow rate-adjusting valve while supplying air to the second space through the second on-off valve and the second flow rate-adjusting valve, thereby pressing and moving the piston in the cylinder in the other direction in which the valve body opens the opening portion such that the first on-off valve is completely closed and air is exhausted only by the first flow rate-adjusting valve immediately before the piston reaches the end in the other direction.

8. The gate valve according to claim 7,
wherein the first and second on-off valves are electromagnetic valves, and
the first and second flow rate-adjusting valves are needle valves.

9. The gate valve according to claim 7, further comprising:
a guide mechanism that includes a movable body which is moved integrally with the valve body, a guide hole to which the movable body is fitted, and a resin stopper,
wherein the movable body is moved in the guide hole to guide the valve body such that the valve body can be moved in a direction in which the passage is divided, and
the resin stopper comes into contact with the movable body when the movable body is disposed at least at one end of the guide hole.
